(19) United States
(12) Patent Application Publication
(10) Pub. No.: US 2026/0181136 A1
(43) Pub. Date: Jun. 25, 2026

(54) PERFORMING IMAGE COMPRESSION USING MIXED-PRECISION MATRIX SKETCHING TO REDUCE STORAGE AND BANDWIDTH REQUIREMENTS

(71) Applicant: International Business Machines Corporation, Armonk, NY (US)

(72) Inventors: Vasileios Kalantzis, New York, NY (US); Tayfun Gokmen, Briarcliff Manor, NY (US); Shashanka Ubaru, Austin, TX (US); Lior Horesh, North Salem, NY (US)

(21) Appl. No.: 18/990,208

(22) Filed: Dec. 20, 2024

(51) Int. Cl. H04N 19/119; H04N 19/132

(52) U.S. Cl. CPC H04N 19/119; H04N 19/132

(57) ABSTRACT

A computer-implemented method, system, and computer program product for image compression using mixed-precision matrix sketching. An input matrix corresponding to an image and a target rank k are received. After creating a sketching matrix of the input matrix, a product of the input matrix and the sketching matrix is computed using 8-bit floating-point precision. The decomposition of the computed product is performed to determine a basis matrix Q using 64-bit floating-point precision. A matrix B, which is smaller than the input matrix, is then computed using the basis matrix Q. A singular value decomposition (SVD) of the matrix B is then computed to obtain right singular vectors V, approximate left singular vectors Ũ and corresponding singular values Σ. After computing the left singular vectors U by pre-multiplying Ũ by the basis matrix Q, the top k singular values and vectors corresponding to U, Σ, and V are selected thereby compressing the image.

### TECHNICAL FIELD

The present disclosure relates generally to image processing, and more particularly to performing image compression using mixed-precision matrix sketching to reduce storage and bandwidth requirements.

### BACKGROUND

An image is an array, or a matrix, of square pixels (picture elements) arranged in columns and rows. Each element of the matrix corresponds to the color value of a single pixel in the image, effectively treating the image as a grid of pixel values arranged in rows and columns. The matrix dimensions correspond to the image resolution (width×height), with each row representing a horizontal line of pixels.

### SUMMARY

In one embodiment of the present disclosure, a computer-implemented method for image compression using mixed-precision matrix sketching comprises receiving an input matrix corresponding to an image. The method further comprises receiving a target rank k. The method additionally comprises creating a sketching matrix of the input matrix. Furthermore, the method comprises computing a product of the input matrix and the sketching matrix using 8-bit floating-point precision. Additionally, the method comprises performing a decomposition of the computed product to determine a basis matrix Q for the input matrix using 64-bit floating-point precision. In addition, the method comprises computing a matrix B, which is smaller than the input matrix, using the basis matrix Q. The method further comprises computing a singular value decomposition of the matrix B to obtain right singular vectors V, approximate left singular vectors Ũ and corresponding singular values Σ. The method additionally comprises computing left singular vectors U by pre-multiplying the approximate left singular vectors Ũ by the basis matrix Q. Furthermore, the method comprises selecting a top k singular values and vectors corresponding to the left singular vectors U, the corresponding singular values Σ, and the right singular vectors V thereby compressing the image.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a computing environment for practicing the principles of the present disclosure;

FIG. 2 illustrates an embodiment of a computer utilizing a floating-point unit to carry out operations on floating-point numbers as well as a digital co-processor, such as a graphics processing unit, to implement hardware acceleration in accordance with an embodiment of the present disclosure;

FIG. 3 illustrates an example configuration for a floating-point representation in accordance with an embodiment of the present disclosure;

FIG. 4 is a diagram of the software components used by the computer to reduce the storage and bandwidth requirements involving the processing of images using mixed-precision matrix sketching in accordance with an embodiment of the present disclosure;

FIGS. 5A-5B illustrate performing the count sketch technique in the map-reduced fashion in accordance with an embodiment of the present disclosure;

FIG. 6 illustrates a conceptual architecture of the singular value decomposition in accordance with an embodiment of the present disclosure;

FIG. 7 illustrates performing a decomposition of the computed product to determine a basis matrix Q in accordance with an embodiment of the present disclosure; and

FIG. 8 is a flowchart of a method for reducing the storage and bandwidth requirements involving the processing of images using mixed-precision matrix sketching in accordance with an embodiment of the present disclosure.

### DETAILED DESCRIPTION

As stated above, an image is an array, or a matrix, of square pixels (picture elements) arranged in columns and rows. Each element of the matrix corresponds to the color value of a single pixel in the image, effectively treating the image as a grid of pixel values arranged in rows and columns. The matrix dimensions correspond to the image resolution (width×height), with each row representing a horizontal line of pixels.

In image processing, where the matrix represents an image and where each element in the matrix corresponds to a pixel in the image, such pixels may be manipulated by applying mathematical operations on the matrix, such as filtering, transformations (rotation, scaling), and color adjustments, to achieve various image processing tasks, such as edge detection, sharpening, or brightness adjustments. That is, each pixel's value is calculated based on its surrounding pixels within the matrix, enabling complex image modifications through matrix operations.

Due to the large computational and memory requirements for image processing, hardware acceleration may be utilized. Hardware acceleration is a process that moves some computing tasks, such as image processing, from a computer's central processing unit (CPU) to specialized hardware components, such as a graphics processing unit (GPU). This can significantly increase efficiency and performance.

While utilizing hardware acceleration for image processing has improved efficiency and performance, computational and memory requirements of algorithms for processing images in the form of matrices is still quite extensive due to the large amount of storage space required to store the images and the large amount of bandwidth required to send the images to other devices.

For example, 16-bit floating-point precision is used in image processing. 16-point floating-point precision, also known as half precision or binary 16, is a computer number format that uses 16 bits to store floating-point values. It is used in applications where higher precision is not essential, such as image processing and neural networks.

As a result of using 16-bit floating-point precision, images require a large amount of memory (storage space) and require a large bandwidth in order to be sent to other devices. Such storage and bandwidth requirements need to be reduced in order to improve performance and enhance user experience.

The embodiments of the present disclosure provide a means for reducing the storage and bandwidth requirements involving the processing of images as matrices using mixed-precision matrix sketching. Mixed-precision, as used herein, refers to using different floating-point types (e.g., both 8-bit and 16-bit floating-point types). Matrix sketching, as used herein, refers to an algorithm that compresses an input matrix to another matrix which is significantly smaller than the input matrix but it still approximates it well. In one embodiment, a sketching matrix of a received matrix is created. Such a sketching matrix may be created using the count sketch technique or based on a drawing of a random test matrix Ω, where the values of the random test matrix Ω are ±1. In one embodiment, the count sketch technique is implemented by hashing each column of the input matrix with a value uniformly sampled from a range of sketch sizes. A sign of each column with probability 50% is flipped and then the columns with the same hash value are summed up. In one embodiment, the random test matrix Ω is constructed by drawing entries from a normal distribution, by drawing entries from a uniform distribution, or by drawing independent Rademacher entries. The product of the input matrix and the sketching matrix is then computed using 8-bit floating point precision. By using 8-bit floating-point precision, the required storage and bandwidth for image processing is reduced. Such a computed product may then be stored in 8-bit floating-point notation. Such a product may then be extended to 64-bit floating-point precision during the computational phase thereby reducing the necessary bandwidth by a factor of 8. For example, a decomposition of the computed product is performed to determine a basis matrix Q for the input matrix using 64-bit floating-point precision. A matrix B, which is smaller than the input matrix, is computed using the basis matrix Q. In one embodiment, matrix B is obtained by projecting the input matrix to low-dimensional space. A singular value decomposition of matrix B is then computed to obtain the right singular vectors V, the approximate left singular vectors Ũ, and the corresponding singular values Σ. In one embodiment, the left singular vectors U are computed by pre-multiplying the approximate left singular vectors Ũ by the basis matrix Q. The top k singular values and vectors are then selected corresponding to the left singular vectors U, the corresponding singular values Σ, and the right singular vectors V thereby compressing the image. In this manner, the storage and bandwidth requirements involving the processing of images as matrices are reduced using mixed-precision (both 8-bit and 64-bit floating-point precision) matrix sketching. A further discussion regarding these and other features is provided below.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

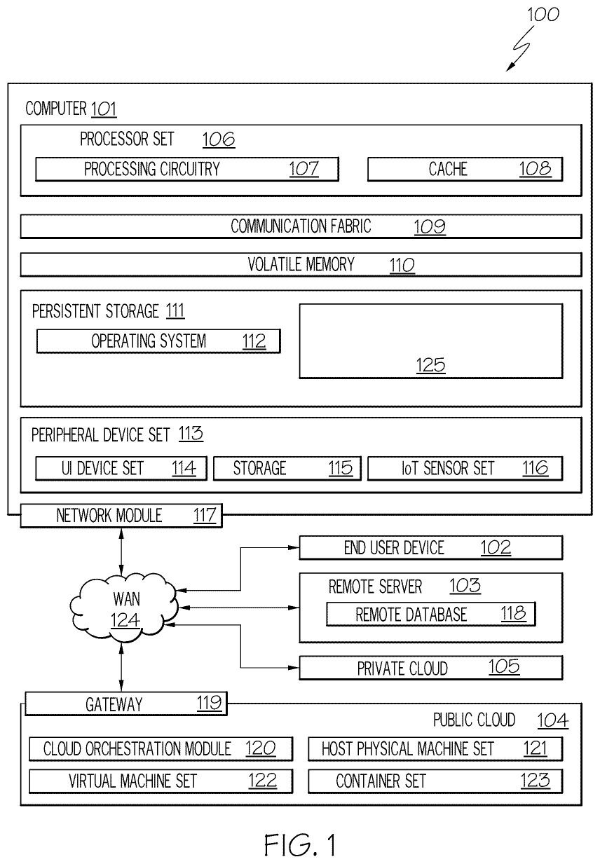

Referring now to the Figures in detail, FIG. 1 illustrates an embodiment of the present disclosure of a computing environment 100 for practicing the principles of the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code (stored in block 125) involved in performing the inventive methods, such as reducing the storage and bandwidth requirements involving the processing of images as matrices using mixed-precision matrix sketching. In addition to block 125, computing environment 100 includes, for example, computer 101, network 124, such as a wide area network (WAN), end user device (EUD) 102, remote server 103, public cloud 104, and private cloud 105. In this embodiment, computer 101 includes processor set 106 (including processing circuitry 107 and cache 108), communication fabric 109, volatile memory 110, persistent storage 111 (including operating system 112 and block 125, as identified above), peripheral device set 113 (including user interface (UI) device set 114, storage 115, and Internet of Things (IoT) sensor set 116), and network module 117. Remote server 103 includes remote database 118. Public cloud 104 includes gateway 119, cloud orchestration module 120, host physical machine set 121, virtual machine set 122, and container set 123.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 118. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 106 includes one, or more, computer processors of any type now known or to be developed in the future. Processing circuitry 107 may be distributed over multiple packages, for example, multiple, coordinated integrated circuit chips. Processing circuitry 107 may implement multiple processor threads and/or multiple processor cores. Cache 108 is memory that is located in the processor chip package(s) and is typically used for data or code that should be available for rapid access by the threads or cores running on processor set 106. Cache memories are typically organized into multiple levels depending upon relative proximity to the processing circuitry. Alternatively, some, or all, of the cache for the processor set may be located “off chip.” In some computing environments, processor set 106 may be designed for working with qubits and performing quantum computing.

Computer readable program instructions are typically loaded onto computer 101 to cause a series of operational steps to be performed by processor set 106 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 108 and the other storage media discussed below. The program instructions, and associated data, are accessed by processor set 106 to control and direct performance of the inventive methods. In computing environment 100, at least some of the instructions for performing the inventive methods may be stored in block 125 in persistent storage 111.

Communication fabric 109 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 110 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 110 is located in a single package and is internal to computer 101, but, alternatively or additionally, the volatile memory may be distributed over multiple packages and/or located externally with respect to computer 101.

Persistent Storage 111 is any form of non-volatile storage for computers that is now known or to be developed in the future. The non-volatility of this storage means that the stored data is maintained regardless of whether power is being supplied to computer 101 and/or directly to persistent storage 111. Persistent storage 111 may be a read only memory (ROM), but typically at least a portion of the persistent storage allows writing of data, deletion of data and re-writing of data. Some familiar forms of persistent storage include magnetic disks and solid state storage devices. Operating system 112 may take several forms, such as various known proprietary operating systems or open source Portable Operating System Interface type operating systems that employ a kernel. The code included in block 125 typically includes at least some of the computer code involved in performing the inventive methods.

Peripheral device set 113 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 114 may include components such as a display screen, speaker, microphone, wearable devices (such as goggles and smart watches), keyboard, mouse, printer, touchpad, game controllers, and haptic devices. Storage 115 is external storage, such as an external hard drive, or insertable storage, such as an SD card. Storage 115 may be persistent and/or volatile. In some embodiments, storage 115 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 116 is made up of sensors that can be used in Internet of Things applications. For example, one sensor may be a thermometer and another sensor may be a motion detector.

Network module 117 is the collection of computer software, hardware, and firmware that allows computer 101 to communicate with other computers through WAN 124. Network module 117 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 117 are performed on the same physical hardware device. In other embodiments (for example, embodiments that utilize software-defined networking (SDN)), the control functions and the forwarding functions of network module 117 are performed on physically separate devices, such that the control functions manage several different network hardware devices. Computer readable program instructions for performing the inventive methods can typically be downloaded to computer 101 from an external computer or external storage device through a network adapter card or network interface included in network module 117.

WAN 124 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 102 is any computer system that is used and controlled by an end user (for example, a customer of an enterprise that operates computer 101), and may take any of the forms discussed above in connection with computer 101. EUD 102 typically receives helpful and useful data from the operations of computer 101. For example, in a hypothetical case where computer 101 is designed to provide a recommendation to an end user, this recommendation would typically be communicated from network module 117 of computer 101 through WAN 124 to EUD 102. In this way, EUD 102 can display, or otherwise present, the recommendation to an end user. In some embodiments, EUD 102 may be a client device, such as thin client, heavy client, mainframe computer, desktop computer and so on.

Remote server 103 is any computer system that serves at least some data and/or functionality to computer 101. Remote server 103 may be controlled and used by the same entity that operates computer 101. Remote server 103 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 118 of remote server 103.

Public cloud 104 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 104 is performed by the computer hardware and/or software of cloud orchestration module 120. The computing resources provided by public cloud 104 are typically implemented by virtual computing environments that run on various computers making up the computers of host physical machine set 121, which is the universe of physical computers in and/or available to public cloud 104. The virtual computing environments (VCEs) typically take the form of virtual machines from virtual machine set 122 and/or containers from container set 123. It is understood that these VCEs may be stored as images and may be transferred among and between the various physical machine hosts, either as images or after instantiation of the VCE. Cloud orchestration module 120 manages the transfer and storage of images, deploys new instantiations of VCEs and manages active instantiations of VCE deployments. Gateway 119 is the collection of computer software, hardware, and firmware that allows public cloud 104 to communicate through WAN 124.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 105 is similar to public cloud 104, except that the computing resources are only available for use by a single enterprise. While private cloud 105 is depicted as being in communication with WAN 124 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 104 and private cloud 105 are both part of a larger hybrid cloud.

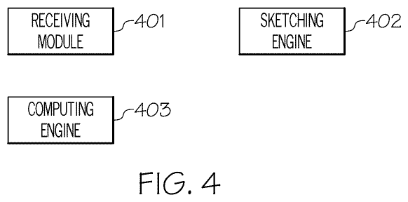

Block 125 further includes the software components discussed herein in connection with FIGS. 4, 5A-5B and 6-7 to reduce the storage and bandwidth requirements involving the processing of images as matrices using mixed-precision matrix sketching. In one embodiment, such components may be implemented in hardware. The functions discussed above performed by such components are not generic computer functions. As a result, computer 101 is a particular machine that is the result of implementing specific, non-generic computer functions.

In one embodiment, the functionality of such software components of computer 101, including the functionality for reducing the storage and bandwidth requirements involving the processing of images as matrices using mixed-precision matrix sketching, may be embodied in an application specific integrated circuit.

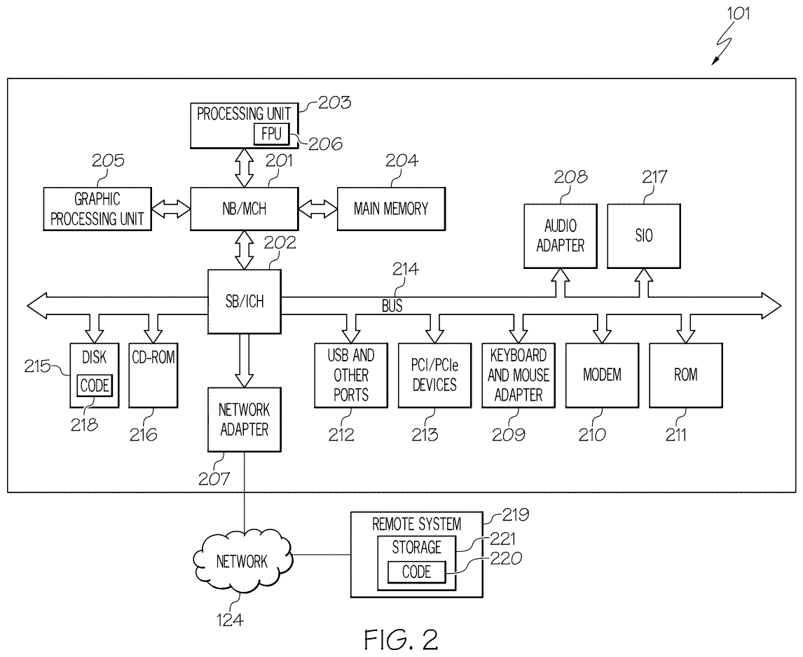

An embodiment of computer 101 utilizing a floating-point unit to carry out operations on floating-point numbers as well as a digital co-processor, such as a graphics processing unit, to implement hardware acceleration is discussed below in connection with FIG. 2.

FIG. 2 illustrates an embodiment of computer 101 utilizing a floating-point unit to carry out operations on floating-point numbers as well as a digital co-processor, such as a graphics processing unit, to implement hardware acceleration in accordance with an embodiment of the present disclosure.

Referring now to FIG. 2, in conjunction with FIG. 1, computer 101 employs a hub architecture including North Bridge and memory controller hub (NB/MCH) 201 and South Bridge and input/output (I/O) controller hub (SB/ICH) 202. Processing unit 203, main memory 204, and the digital co-processor to implement hardware acceleration, such as graphics processing unit 205, are connected to North Bridge and memory controller hub (NB/MCH) 201. Processing unit 203 may contain one or more processors and may be implemented using one or more heterogeneous processor systems. For example, processing unit 203 includes floating-point unit (FPU) 206 configured to perform mathematical calculations on floating-point numbers. In one embodiment, processing unit 203 is a multi-core processor. In one embodiment, graphics processing unit 205 is connected to NB/MCH 201 through an accelerated graphics port (AGP) in certain implementations.

In the depicted example, local area network (LAN) adapter 207 is connected to South Bridge and I/O controller hub (SB/ICH) 202. Audio adapter 208, keyboard and mouse adapter 209, modem 210, read only memory (ROM) 211, universal serial bus (USB) and other ports 212, and PCI/PCIe devices 213 are connected to South Bridge and I/O controller hub 202 through bus 214. Hard disk drive (HDD) or solid-state drive (SSD) 215 and CD-ROM 216 are connected to South Bridge and I/O controller hub 202 through bus 214. PCI/PCIe devices 213 may include, for example, Ethernet adapters, add-in cards, and PC cards for notebook computers. PCI uses a card bus controller, while PCIe does not. ROM 211 may be, for example, a flash binary input/output system (BIOS). Hard disk drive 215 and CD-ROM 216 may use, for example, an integrated drive electronics (IDE), serial advanced technology attachment (SATA) interface, or variants, such as external-SATA (eSATA) and micro-SATA (mSATA). A super I/O (SIO) device 217 may be connected to South Bridge and I/O controller hub (SB/ICH) 202 through bus 214.

Memories, such as main memory 204, ROM 211, or flash memory (not shown), are some examples of computer usable storage devices. Hard disk drive or solid state drive 215, CD-ROM 216, and other similarly usable devices are some examples of computer usable storage devices including a computer usable storage medium.

An operating system runs on processing unit 203. The operating system coordinates and provides control of various components within computer 101 in FIG. 2. The operating system may be a commercially available operating system for any type of computing platform, including, but not limited to, server systems, personal computers, and mobile devices. An object oriented or other type of programming system may operate in conjunction with the operating system and provide calls to the operating system from programs or applications executing on computer 101.

Instructions for the operating system, the object-oriented programming system, and applications or programs, such as applications stored in block 125 of FIG. 1, are located on storage devices, such as in the form of code 218 on hard disk drive 215, and may be loaded into at least one of one or more memories, such as main memory 204, for execution by processing unit 203. The processes of the illustrative embodiments may be performed by processing unit 203 using computer implemented instructions, which may be located in a memory, such as, for example, main memory 204, read only memory 211, or in one or more peripheral devices.

Furthermore, in one embodiment, code 218 is downloaded over network 124 from remote system 219, where similar code 220 is stored on a storage device 221. In one embodiment, code 218 is downloaded over network 124 to remote system 219, where downloaded code 220 is stored on storage device 221.

The hardware in FIGS. 1-2 may vary depending on the implementation. Other internal hardware or peripheral devices, such as flash memory, equivalent non-volatile memory, or optical disk drives and the like, may be used in addition to or in place of the hardware depicted in FIGS. 1-2. In addition, the processes of the illustrative embodiments may be applied to a multiprocessor computing system.

Furthermore, the depicted examples in FIGS. 1-2 and above-described examples are not meant to imply architectural limitations.

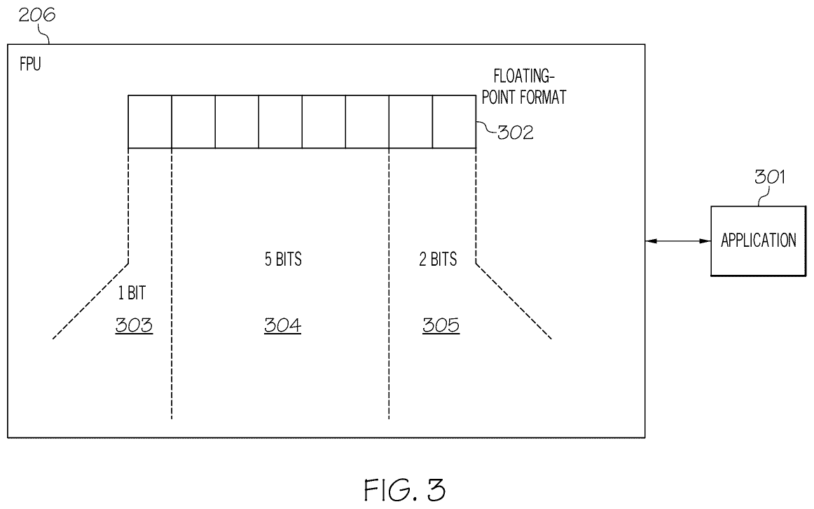

Referring now to FIG. 3, in conjunction with FIGS. 1-2, FIG. 3 illustrates an example configuration for a floating-point representation in accordance with an embodiment of the present disclosure. Application 301 is an example of an application stored in block 125 of FIG. 1.

As previously discussed, floating-point unit 206 performs mathematical calculations on floating-point numbers, including calculations being performed to compress an image, such as a matrix corresponding to an image, using singular value decomposition. In particular, floating-point unit 206 performs mathematical calculations on floating-point numbers involving the computation of finding the reduced rank approximation of a matrix (matrix corresponding to an image) by selecting the top k singular values and vectors using the rank-k truncated singular value decomposition method.

In one embodiment, such calculations involve processing of images as matrices using mixed-precision. As stated above, mixed-precision, as used herein, refers to using different floating-point types (e.g., both 8-bit and 16-bit floating-point types). In particular, the product of the input matrix with the sketching matrix is computed using 8-bit floating point precision. By using 8-bit floating-point precision, the required storage and bandwidth for image processing is reduced. Such a product may then be extended to 64-bit floating-point precision during the computational phase thereby reducing the necessary bandwidth by a factor of 8. An example of the format (see element 302) of an 8-bit floating point number is shown in FIG. 3.

Referring to format 302 of an 8-bit floating point number, the highest 1 bit is reserved as a sign bit 303, the next lower 5 bits are reserved as exponent bits 304, and the lowest 2 bits are reserved as mantissa bits 305. In one embodiment (not shown), the highest 1 bit is reserved as a sign bit 303, the next lower 6 bits are reserved as exponent bits 304, and the lowest bit is reserved as a mantissa bit 305.

A discussion regarding the software components used by computer 101 to reduce the storage and bandwidth requirements involving the processing of images using mixed-precision matrix sketching is provided below in connection with FIG. 4.

FIG. 4 is a diagram of the software components used by computer 101 to reduce the storage and bandwidth requirements involving the processing of images using mixed-precision matrix sketching in accordance with an embodiment of the present disclosure.

Referring to FIG. 4, in conjunction with FIGS. 1-3, computer 101 includes receiving module 401 configured to receive a matrix (e.g., m×n matrix, where m represents the number of rows and n represents the number of columns within the matrix) (referred to herein as the “input matrix” represented by the letter A) corresponding to an image as well as the target rank k in connection with computer 101 computing the rank-k truncated singular value decomposition by mixed-precision matrix sketching. Such an approach compresses images by approximating the input matrix. In particular, such an approach (singular value decomposition) refactors the given image (input matrix) into three matrices. Singular values are used to refactor the image, and at the end of the process, the image is represented with a smaller set of values thereby reducing the storage space required by the image. As a result, computing the k leading singular triplets (rank-k truncated singular value decomposition) results in reducing the storage and bandwidth requirements of images. That is, the low-rank singular decomposition provides the optimal rank-k reconstruction of the input matrix A, which is represented as Ak. A discussion regarding computing the k leading singular triplets (rank-k truncated singular value decomposition) by mixed-precision matrix sketching is discussed below.

In one embodiment, receiving module 401 receives the input matrix (e.g., m×n matrix) corresponding to an image as well as the target rank k from a user of computer 101. In one embodiment, the input matrix (e.g., m×n matrix) corresponding to an image as well as the target rank k is inputted by the user of computer 101 via various means, such as via a keyboard, mouse and/or touch screen.

In one embodiment, the k leading singular triplets (rank-k truncated singular value decomposition) is computed by first creating a sketching matrix S of the input matrix A as discussed below. In one embodiment, such a sketching matrix S is created by sketching engine 402 of computer 101. In particular, in one embodiment, sketching engine 402 is configured to create an n×s sketching matrix S of the input matrix A, where

$$s = 𝒪 ( \frac{k}{ϵ} ) ,$$

where ε represents an arbitrarily small or infinitesimally small positive quantity, and where [symbol] refers to operations, such as floating-point operations.

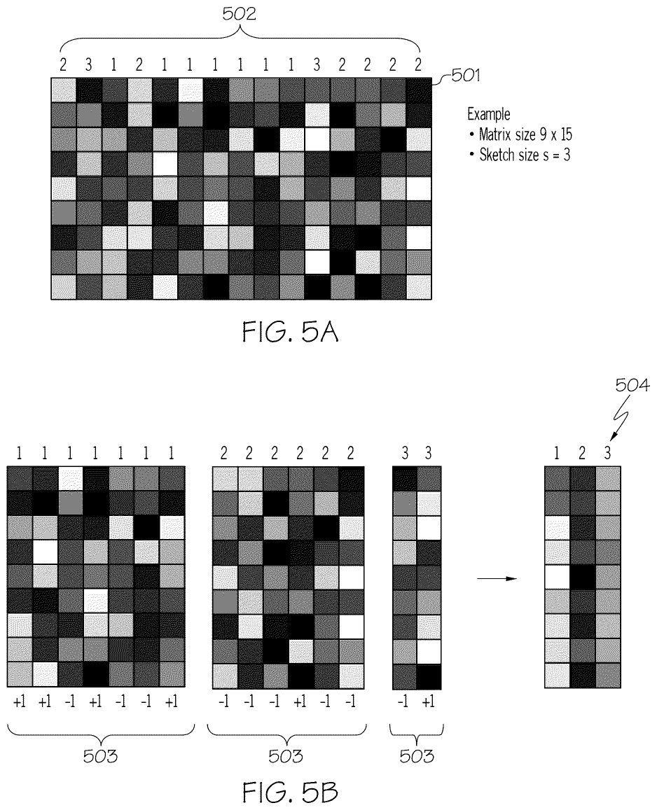

In one embodiment, sketching engine 402 creates a sketching matrix S of the input matrix A using various means, including using the count sketch technique. The count sketch technique is an algorithm that produces a sketch of an input matrix, where the sketched matrix is much smaller than the input matrix while preserving most of its properties. An illustration of the count sketch technique is provided in FIGS. 5A-5B.

FIGS. 5A-5B illustrate performing the count sketch technique in the map-reduced fashion in accordance with an embodiment of the present disclosure.

As shown in FIGS. 5A-5B, the count sketch technique may be performed in the map-reduced fashion which includes three steps. First, each column is hashed with a discrete value uniformly sampled from a range of sketch sizes as shown in FIG. 5A. For instance, each column 501 of a matrix (e.g., 9×15 matrix) is hashed with a discrete value 502 uniformly sampled from a range of sketch sizes(s) (e.g., sketch sizes {1, 2, 3}).

Secondly, the sign of each column 501 with probability 50% is flipped as shown in FIG. 5B. Thirdly, the columns with the same hash value are summed up (see element 503), such as adding it to a uniformly selected column of the matrix as shown in element 504 of FIG. 5B.

In one embodiment, sketching engine 402 implements the count sketch technique discussed above using various software tools, including, but are not limited to, Matlab®, Maple®, Mathematica®, etc.

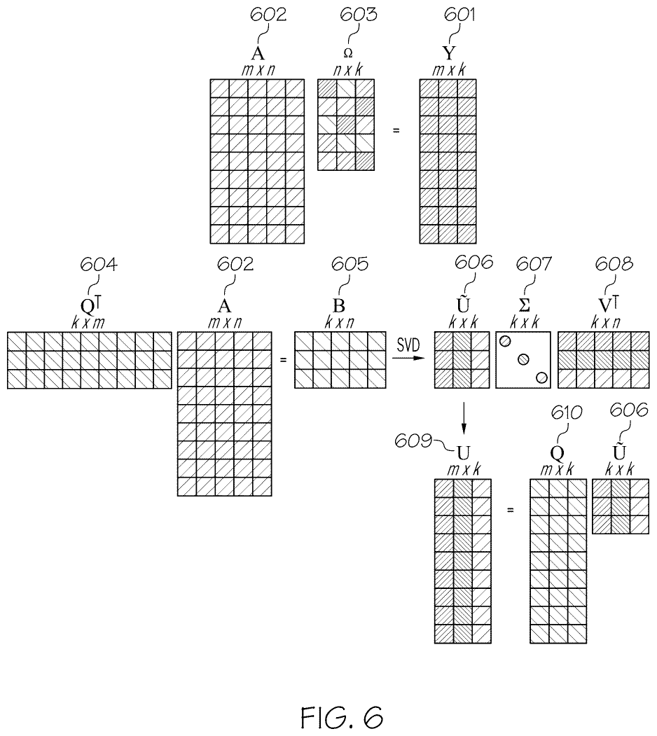

Alternatively, sketching engine 402 creates a sketching matrix S (also identified as Y) of the input matrix A based on a drawing of a random test matrix Ω, where values of the random test matrix Ω are ±1. As previously discussed, the sketching matrix is utilized in computing the rank-k truncated singular value decomposition. Creating such a sketching matrix S (also identified as Y) based on a drawing of a random test matrix Ω in connection with computing the rank-k truncated singular value decomposition is discussed below in connection with FIG. 6.

FIG. 6 illustrates a conceptual architecture of the singular value decomposition in accordance with an embodiment of the present disclosure.

As shown in FIG. 6, the sketching matrix S (also identified as Y) 601 of the input matrix A 602 is created based on a drawing of a random test matrix Ω 603, where values of random test matrix Ω 603 are ±1. In one embodiment, random test matrix Ω 603 is a matrix with independent identically distributed (i.i.d) entries from a distribution, which ensures that its columns are linearly independent with high probability.

In one embodiment, random test matrix Ω 603 is constructed by drawing entries from a standard normal distribution, N (0, 1).

In another embodiment, random test matrix Ω 603 is constructed by drawing entries from a uniform distribution U (−1, 1).

In a further embodiment, random test matrix Ω 603 is constructed by drawing independent Rademacher entries. The Rademacher distribution is a discrete probability distribution, where the random variates take the values +1 and −1 with equal probability.

In one embodiment, sketching engine 402 creates the sketching matrix S based on a drawing of random test matrix Ω 603 using various software tools, including, but are not limited to, Matlab®, Maple®, Mathematica®, etc.

Returning to FIG. 4, in conjunction with FIGS. 1-3, 5A-5B and 6, in connection with computing the k leading singular triplets (rank-k truncated singular value decomposition), computing engine 403 of computer 101 computes the product (C) of the input matrix A and the sketching matrix S using 8-bit floating point precision. That is, C=AS. By using 8-bit floating point precision, the required storage and bandwidth for image processing is reduced.

In one embodiment, the values of A are between zero and one while those of random test matrix Ω 603 are ±1. As a result, the loss in accuracy is bounded.

In one embodiment, the computed product discussed above is stored in 8-bit floating-point notation, such as shown in FIG. 3 (see element 302). For example, in one embodiment, computing engine 403 utilizes floating-point unit 206 to perform such a calculation. In one embodiment, such a calculation is stored in a storage device (e.g., storage device 111, 115) of computer 101.

In one embodiment, such a product is extended to 64-bit floating-point precision during the computational phase thereby reducing the necessary bandwidth by a factor of 8 as discussed below.

For example, in one embodiment, in connection with computing the k leading singular triplets (rank-k truncated singular value decomposition), computing engine 403 further performs a decomposition of the computed product C to determine what is referred to herein as the basis matrix Q for the input matrix A using 64-bit floating-point precision.

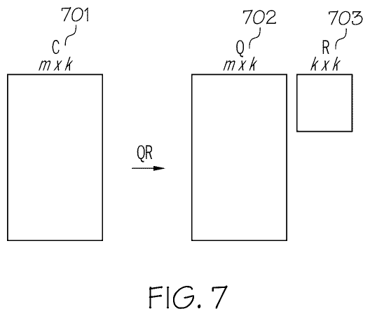

In one embodiment, once C is obtained, the columns are orthonormalized in order to form a natural basis Q∈R m×k as shown in FIG. 7. This can be efficiently achieved using the QR-decomposition C=:QR.

Referring to FIG. 7, FIG. 7 illustrates performing a decomposition of the computed product C to determine a basis matrix Q in accordance with an embodiment of the present disclosure.

As shown in FIG. 7, computing engine 403 performs the decomposition of the computed product matrix C to determine a basis matrix Q for the input matrix A. Decomposition of matrices is a mathematical process where a complex matrix is broken down into a product of simpler matrices, making it easier to perform calculations and analyze the underlying structure of the data represented by the matrix. In one embodiment, computing engine 403 performs the QR decomposition, which expresses the computed product matrix C (m×k, where m represents the number of rows and k represents the number of columns within the matrix) (element 701) as QR with Q (m×k, where m represents the number of rows and k represents the number of columns within the matrix) (element 702), an orthogonal matrix, and R (k×k, where the first k represents the number of rows and the second k represents the number of columns within the matrix) (element 703), an upper triangular matrix. In one embodiment, computing engine 403 performs such a computation using the qr function in Matlab®. Other software tools that may be used by computing engine 403 to perform such a computation include, but are not limited to, Maple®, Mathematica®, etc.

Returning to FIG. 4, in one embodiment, in connection with computing the k leading singular triplets (rank-k truncated singular value decomposition), computing engine 403 further computes a matrix B, which is smaller than the input matrix A, using the basis matrix Q.

In one embodiment, computing engine 403 identifies the smaller matrix B∈R k×n, i.e., the elements of the matrix B correspond to the set of real numbers formed by k×n, where k represents the number of rows and n represents the number of columns within the matrix.

As a result, the high-dimensional input matrix A is projected to low-dimensional space B:=Q>A. Geometrically, this is a projection (i.e., a linear transformation) which takes points in a high-dimensional space into corresponding points in a low-dimensional space. Such a process preserves the geometric structure of the data in an Euclidean sense, i.e., the length of the projected vectors as well as the angles between the projected vectors are preserved due to the invariance of inner products.

In one embodiment, computing engine 403 computes the smaller matrix B 605 (k×n matrix, where k represents the number of rows and n represents the number of columns within the matrix) based on computing the product of the transpose version of the basis matrix (QT) 604 (k×m matrix, where k represents the number of rows and m represents the number of columns within the matrix) with the input matrix A 602 (m×n matrix, where m represents the number of rows and n represents the number of columns within the matrix) as shown in FIG. 6.

In one embodiment, such a computation is performed by computing engine 403 using various software tools, including, but are not limited to, Matlab® (e.g., svd function), Maple®, Mathematica®, etc.

In one embodiment, in connection with computing the k leading singular triplets (rank-k truncated singular value decomposition), computing engine 403 further computes a singular value decomposition (SVD) of matrix B to obtain the right singular vectors V, the approximate left singular vectors Ũ and the corresponding singular values Σ as shown in FIG. 6.

For example, computing the SVD of matrix B 605 results in the approximate left singular vectors Ũ 606 (k×k matrix, where the first k represents the number of rows and the second k represents the number of columns within the matrix), the corresponding singular values Σ 607 (k×k matrix, where the first k represents the number of rows and the second k represents the number of columns within the matrix), and the right singular vectors V (k×n matrix, where k represents the number of rows and n represents the number of columns within the matrix), such as transposed right singular vectors V^{T} 608.

For instance, in one embodiment, computing engine 403 computes the full SVD of matrix B using a deterministic algorithm B=ŨΣV^{T}. In one embodiment, such a computation is performed by computing engine 403 using various software tools, including, but are not limited to, Matlab® (e.g., svd function), Maple®, Mathematica®, etc.

Furthermore, computing engine 403 computes the left singular vectors U 609 (m×k matrix, where m represents the number of rows and k represents the number of columns within the matrix) by pre-multiplying the approximate left singular vectors Ũ 606 by the basis matrix Q 610 (m×k matrix, where m represents the number of rows and k represents the number of columns within the matrix) as shown in FIG. 6. In one embodiment, such a computation is performed by computing engine 403 using various software tools, including, but are not limited to, Matlab® (e.g., svd function), Maple®, Mathematica®, etc.

Additionally, in one embodiment, in connection with computing the k leading singular triplets (rank-k truncated singular value decomposition), since Aₖ≈UΣV^{T}, computing engine 403 selects the top k singular values and vectors corresponding to the left singular vectors U 609, the corresponding singular values Σ 607, and the right singular vectors V 608. Such singular values and vectors are used to refactor the image of the input matrix A thereby representing the image with a smaller set of values (compressing the image). In this manner, the storage and bandwidth requirements involved in the processing of images as matrices are reduced using mixed-precision (both 8-bit and 64-bit floating-point precision) matrix sketching.

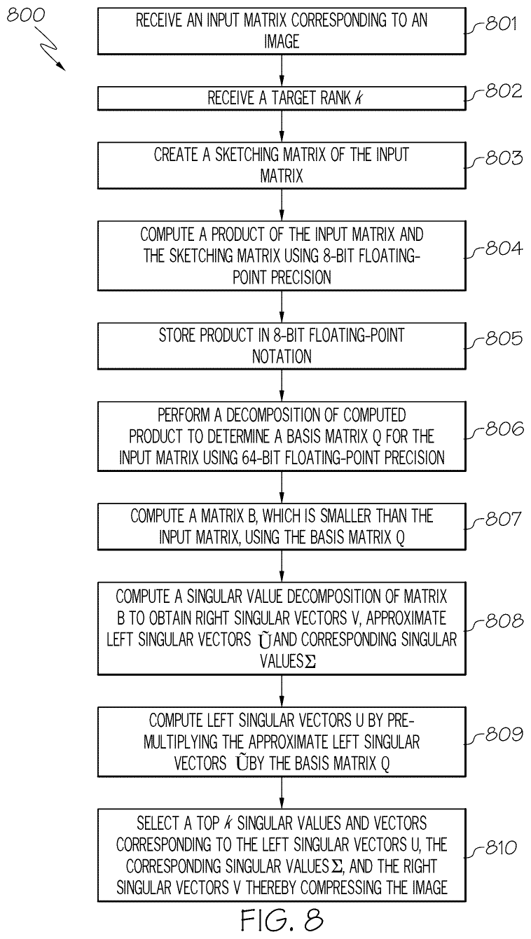

A discussion regarding the method for reducing the storage and bandwidth requirements involving the processing of images using mixed-precision matrix sketching is provided below in connection with FIG. 8.

FIG. 8 is a flowchart of a method 800 for reducing the storage and bandwidth requirements involving the processing of images using mixed-precision matrix sketching in accordance with an embodiment of the present disclosure.

Referring to FIG. 8, in conjunction with FIGS. 1-4, 5A-5B and 6-7, in step 801, receiving module 401 of computer 101 receives a matrix (e.g., m×n matrix, where m represents the number of rows and n represents the number of columns within the matrix) (referred to herein as the “input matrix” represented by the letter A) corresponding to an image.

As discussed above, in one embodiment, receiving module 401 receives the input matrix (e.g., m×n matrix) corresponding to an image from the user, such as the user of computer 101, via various means, such as via a keyboard, mouse and/or touch screen.

In step 802, receiving module 401 of computer 101 receives the target rank k in connection with computer 101 computing the rank-k truncated singular value decomposition by mixed-precision matrix sketching.

As stated above, in one embodiment, receiving module 401 receives the target rank k from the user, such as the user of computer 101, via various means, such as via a keyboard, mouse and/or touch screen.

Furthermore, as stated above, by computing the rank-k truncated singular value decomposition, images represented by an input matrix are compressed by approximating the input matrix. In particular, such an approach (singular value decomposition) refactors the given image (input matrix) into three matrices. Singular values are used to refactor the image, and at the end of the process, the image is represented with a smaller set of values thereby reducing the storage space required by the image. As a result, computing the k leading singular triplets (rank-k truncated singular value decomposition) results in reducing the storage and bandwidth requirements of images. That is, the low-rank singular decomposition provides the optimal rank-k reconstruction of the input matrix A, which is represented as Ak. The k leading singular triplets (rank-k truncated singular value decomposition) are computed using the steps discussed below.

In step 803, sketching engine 402 of computer 101 creates a sketching matrix S of the input matrix A.

As discussed above, in one embodiment, sketching engine 402 creates an n×s sketching matrix S of the input matrix A, where

$$s = 𝒪 ( \frac{k}{ϵ} ) ,$$

where ε represents an arbitrarily small or infinitesimally small positive quantity, and where [symbol] refers to operations, such as floating-point operations.

In one embodiment, sketching engine 402 creates a sketching matrix S of the input matrix A using various means, including using the count sketch technique. The count sketch technique is an algorithm that produces a sketch of an input matrix, where the sketched matrix is much smaller than the input matrix while preserving most of its properties. An illustration of the count sketch technique is provided in FIGS. 5A-5B.

As shown in FIGS. 5A-5B, the count sketch technique may be performed in the map-reduced fashion which includes three steps. First, each column is hashed with a discrete value uniformly sampled from a range of sketch sizes as shown in FIG. 5A. For instance, each column 501 of a matrix (e.g., 9×15 matrix) is hashed with a discrete value 502 uniformly sampled from a range of sketch sizes(s) (e.g., sketch sizes {1, 2, 3}).

Secondly, the sign of each column 501 with probability 50% is flipped as shown in FIG. 5B. Thirdly, the columns with the same hash value are summed up (see element 503), such as adding it to a uniformly selected column of the matrix as shown in element 504 of FIG. 5B.

In one embodiment, sketching engine 402 implements the count sketch technique discussed above using various software tools, including, but are not limited to, Matlab®, Maple®, Mathematica®, etc.

Alternatively, sketching engine 402 creates a sketching matrix S (also identified as Y) of the input matrix A based on a drawing of a random test matrix Ω, where values of the random test matrix Ω are ±1. As previously discussed, the sketching matrix is utilized in computing the rank-k truncated singular value decomposition. Creating such a sketching matrix S (also identified as Y) based on a drawing of a random test matrix Ω in connection with computing the rank-k truncated singular value decomposition is discussed below in connection with FIG. 6.

As shown in FIG. 6, the sketching matrix S (also identified as Y) 601 of the input matrix A 602 is created based on a drawing of a random test matrix Ω 603, where values of random test matrix Ω 603 are ±1. In one embodiment, random test matrix Ω 603 is a matrix with independent identically distributed (i.i.d) entries from a distribution, which ensures that its columns are linearly independent with high probability.

In one embodiment, random test matrix Ω 603 is constructed by drawing entries from a standard normal distribution, N (0, 1).

In another embodiment, random test matrix Ω 603 is constructed by drawing entries from a uniform distribution U (−1, 1).

In a further embodiment, random test matrix Ω 603 is constructed by drawing independent Rademacher entries. The Rademacher distribution is a discrete probability distribution, where the random variates take the values +1 and −1 with equal probability.

In one embodiment, sketching engine 402 creates the sketching matrix S based on a drawing of random test matrix Ω 603 using various software tools, including, but are not limited to, Matlab®, Maple®, Mathematica®, etc.

In step 804, computing engine 403 of computer 101 computes the product C of the input matrix A and the sketching matrix S using 8-bit floating point precision. That is, C=AS. By using 8-bit floating point precision, the required storage and bandwidth for image processing is reduced.

As stated above, in one embodiment, the values of A are between zero and one while those of random test matrix Ω 603 are ±1. As a result, the loss in accuracy is bounded.

In step 805, computing engine 403 of computer 101 stores the computed product C in 8-bit floating-point notation, such as shown in FIG. 3 (see element 302). For example, in one embodiment, computing engine 403 utilizes floating-point unit 206 to perform such a calculation. In one embodiment, such a calculation is stored in a storage device (e.g., storage device 111, 115) of computer 101.

In one embodiment, such a product is extended to 64-bit floating-point precision during the computational phase thereby reducing the necessary bandwidth by a factor of 8.

In step 806, computing engine 403 of computer 101 performs a decomposition of the computed product (matrix C) to determine the basis matrix Q for the input matrix A using 64-bit floating-point precision.

As discussed above, in one embodiment, once C is obtained, the columns are orthonormalized in order to form a natural basis Q∈R m×k as shown in FIG. 7. This can be efficiently achieved using the QR-decomposition C=:QR

As shown in FIG. 7, computing engine 403 performs the decomposition of the computed product matrix C to determine a basis matrix Q for the input matrix A. Decomposition of matrices is a mathematical process where a complex matrix is broken down into a product of simpler matrices, making it easier to perform calculations and analyze the underlying structure of the data represented by the matrix. In one embodiment, computing engine 403 performs the QR decomposition, which expresses the computed product matrix C (m×k, where m represents the number of rows and k represents the number of columns within the matrix) (element 701) as QR with Q (m×k, where m represents the number of rows and k represents the number of columns within the matrix) (element 702), an orthogonal matrix, and R (k×k, where the first k represents the number of rows and the second k represents the number of columns within the matrix) (element 703), an upper triangular matrix. In one embodiment, computing engine 403 performs such a computation using the qr function in Matlab®. Other software tools that may be used by computing engine 403 to perform such a computation include, but are not limited to, Maple®, Mathematica®, etc.

In step 807, computing engine 403 of computer 101 computes a matrix B, which is smaller than the input matrix A, using the basis matrix Q.

As stated above, in one embodiment, computing engine 403 identifies the smaller matrix B∈R k×n, i.e., the elements of the matrix B correspond to the set of real numbers formed by k×n, where k represents the number of rows and n represents the number of columns within the matrix.

As a result, the high-dimensional input matrix A is projected to low-dimensional space B:=Q>A. Geometrically, this is a projection (i.e., a linear transformation) which takes points in a high-dimensional space into corresponding points in a low-dimensional space. Such a process preserves the geometric structure of the data in an Euclidean sense, i.e., the length of the projected vectors as well as the angles between the projected vectors are preserved due to the invariance of inner products.

In one embodiment, computing engine 403 computes the smaller matrix B 605 (k×n matrix, where k represents the number of rows and n represents the number of columns within the matrix) based on computing the product of the transpose version of the basis matrix (Q^{T}) 604 (k×m matrix, where k represents the number of rows and m represents the number of columns within the matrix) with the input matrix A 602 (m×n matrix, where m represents the number of rows and n represents the number of columns within the matrix) as shown in FIG. 6.

In one embodiment, such a computation is performed by computing engine 403 using various software tools, including, but are not limited to, Matlab® (e.g., svd function), Maple®, Mathematica®, etc.

In step 808, computing engine 403 of computer 101 computes a singular value decomposition (SVD) of matrix B to obtain the right singular vectors V, the approximate left singular vectors Ũ and the corresponding singular values Σ as shown in FIG. 6.

For example, computing the SVD of matrix B 605 results in the approximate left singular vectors Ũ 606 (k×k matrix, where the first k represents the number of rows and the second k represents the number of columns within the matrix), the corresponding singular values Σ 607 (k×k matrix, where the first k represents the number of rows and the second k represents the number of columns within the matrix), and the right singular vectors V (k×n matrix, where k represents the number of rows and n represents the number of columns within the matrix), such as transposed right singular vectors V^{T} 608.

For instance, in one embodiment, computing engine 403 computes the full SVD of matrix B using a deterministic algorithm B=ŨΣV^{T}. In one embodiment, such a computation is performed by computing engine 403 using various software tools, including, but are not limited to, Matlab® (e.g., svd function), Maple®, Mathematica®, etc.

In step 809, computing engine 403 of computer 101 computes the left singular vectors U 609 (m×k matrix, where m represents the number of rows and k represents the number of columns within the matrix) by pre-multiplying the approximate left singular vectors Ũ 606 by the basis matrix Q 610 (m×k matrix, where m represents the number of rows and k represents the number of columns within the matrix) as shown in FIG. 6. In one embodiment, such a computation is performed by computing engine 403 using various software tools, including, but are not limited to, Matlab® (e.g., svd function), Maple®, Mathematica®, etc.

Since Aₖ≈UΣV^{T}, then, in step 810, computing engine 403 of computer 101 selects the top k singular values and vectors corresponding to the left singular vectors U 609, the corresponding singular values Σ 607, and the right singular vectors V 608. Such singular values and vectors are used to refactor the image of the input matrix A thereby representing the image with a smaller set of values (compressing the image).

In this manner, the storage and bandwidth requirements involved in the processing of images as matrices are reduced using mixed-precision (both 8-bit and 64-bit floating-point precision) matrix sketching.

Furthermore, by using 8-bit floating-point hardware, such as floating-point unit 206, for part of the computations allows a near real-time analysis.

Furthermore, the principles of the present disclosure improve the technology or technical field involving image processing.

As discussed above, in image processing, where the matrix represents an image and where each element in the matrix corresponds to a pixel in the image, such pixels may be manipulated by applying mathematical operations on the matrix, such as filtering, transformations (rotation, scaling), and color adjustments, to achieve various image processing tasks, such as edge detection, sharpening, or brightness adjustments. That is, each pixel's value is calculated based on its surrounding pixels within the matrix, enabling complex image modifications through matrix operations. Due to the large computational and memory requirements for image processing, hardware acceleration may be utilized. Hardware acceleration is a process that moves some computing tasks, such as image processing, from a computer's central processing unit (CPU) to specialized hardware components, such as a graphics processing unit (GPU). This can significantly increase efficiency and performance. While utilizing hardware acceleration for image processing has improved efficiency and performance, computational and memory requirements of algorithms for processing images in the form of matrices is still quite extensive due to the large amount of storage space required to store the images and the large amount of bandwidth required to send the images to other devices. For example, 16-bit floating-point precision is used in image processing. 16-point floating-point precision, also known as half precision or binary 16, is a computer number format that uses 16 bits to store floating-point values. It is used in applications where higher precision is not essential, such as image processing and neural networks. As a result of using 16-bit floating-point precision, images require a large amount of memory (storage space) and require a large bandwidth in order to be sent to other devices. Such storage and bandwidth requirements need to be reduced in order to improve performance and enhance user experience.

Embodiments of the present disclosure improve such technology by reducing the storage and bandwidth requirements involving the processing of images as matrices using mixed-precision matrix sketching. Mixed-precision, as used herein, refers to using different floating-point types (e.g., both 8-bit and 16-bit floating-point types). Matrix sketching, as used herein, refers to an algorithm that compresses an input matrix to another matrix which is significantly smaller than the input matrix but it still approximates it well. In one embodiment, a sketching matrix of a received matrix is created. Such a sketching matrix may be created using the count sketch technique or based on a drawing of a random test matrix Ω, where the values of the random test matrix Ω are ±1. In one embodiment, the count sketch technique is implemented by hashing each column of the input matrix with a value uniformly sampled from a range of sketch sizes. A sign of each column with probability 50% is flipped and then the columns with the same hash value are summed up. In one embodiment, the random test matrix Ω is constructed by drawing entries from a normal distribution, by drawing entries from a uniform distribution, or by drawing independent Rademacher entries. The product of the input matrix and the sketching matrix is then computed using 8-bit floating point precision. By using 8-bit floating-point precision, the required storage and bandwidth for image processing is reduced. Such a computed product may then be stored in 8-bit floating-point notation. Such a product may then be extended to 64-bit floating-point precision during the computational phase thereby reducing the necessary bandwidth by a factor of 8. For example, a decomposition of the computed product is performed to determine a basis matrix Q for the input matrix using 64-bit floating-point precision. A matrix B, which is smaller than the input matrix, is computed using the basis matrix Q. In one embodiment, matrix B is obtained by projecting the input matrix to low-dimensional space. A singular value decomposition of matrix B is then computed to obtain the right singular vectors V, the approximate left singular vectors Ũ, and the corresponding singular values Σ. In one embodiment, the left singular vectors U are computed by pre-multiplying the approximate left singular vectors Ũ by the basis matrix Q. The top k singular values and vectors are then selected corresponding to the left singular vectors U, the corresponding singular values Σ, and the right singular vectors V thereby compressing the image. In this manner, the storage and bandwidth requirements involving the processing of images as matrices are reduced using mixed-precision (both 8-bit and 64-bit floating-point precision) matrix sketching. Furthermore, in this manner, there is an improvement in the technical field involving image processing.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for image compression using mixed-precision matrix sketching, the method comprising:
receiving an input matrix corresponding to an image;
receiving a target rank k;
creating a sketching matrix of said input matrix;
computing a product of said input matrix and said sketching matrix using 8-bit floating-point precision;
performing a decomposition of said computed product to determine a basis matrix Q for said input matrix using 64-bit floating-point precision;
computing a matrix B, which is smaller than said input matrix, using said basis matrix Q;
computing a singular value decomposition of said matrix B to obtain right singular vectors V, approximate left singular vectors Ũ and corresponding singular values Σ;
computing left singular vectors U by pre-multiplying said approximate left singular vectors Ũ by said basis matrix Q; and
selecting a top k singular values and vectors corresponding to said left singular vectors U, said corresponding singular values Σ, and said right singular vectors V thereby compressing said image.

2. The method as recited in claim 1, wherein said sketching matrix of said input matrix is created using a count sketch technique.

3. The method as recited in claim 2, wherein said count sketch technique comprises:
hashing each column of said input matrix with a value uniformly sampled from a range of sketch sizes; and
flipping a sign of each column with probability 50%, and then summing up columns with a same hash value.

4. The method as recited in claim 1, wherein said sketching matrix of said input matrix is created based on a drawing of a random test matrix Ω, wherein values of said random test matrix Ω are ±1.

5. The method as recited in claim 4, wherein said random test matrix Ω is constructed by drawing entries from a normal distribution, drawing entries from a uniform distribution, or drawing independent Rademacher entries.

6. The method as recited in claim 1, wherein values of said input matrix are between zero and one.

7. The method as recited in claim 1 further comprising:
storing said computed product in 8-bit floating-point notation.

8. A computer program product for image compression using mixed-precision matrix sketching, the computer program product comprising one or more computer readable storage mediums having program code embodied therewith, the program code comprising programming instructions for:
receiving an input matrix corresponding to an image;
receiving a target rank k;
creating a sketching matrix of said input matrix;
computing a product of said input matrix and said sketching matrix using 8-bit floating-point precision;
performing a decomposition of said computed product to determine a basis matrix Q for said input matrix using 64-bit floating-point precision;
computing a matrix B, which is smaller than said input matrix, using said basis matrix Q;
computing a singular value decomposition of said matrix B to obtain right singular vectors V, approximate left singular vectors Ũ and corresponding singular values Σ;
computing left singular vectors U by pre-multiplying said approximate left singular vectors Ũ by said basis matrix Q; and
selecting a top k singular values and vectors corresponding to said left singular vectors U, said corresponding singular values Σ, and said right singular vectors V thereby compressing said image.

9. The computer program product as recited in claim 8, wherein said sketching matrix of said input matrix is created using a count sketch technique.

10. The computer program product as recited in claim 9, wherein said count sketch technique comprises:
hashing each column of said input matrix with a value uniformly sampled from a range of sketch sizes; and
flipping a sign of each column with probability 50%, and then summing up columns with a same hash value.

11. The computer program product as recited in claim 8, wherein said sketching matrix of said input matrix is created based on a drawing of a random test matrix Ω, wherein values of said random test matrix Ω are ±1.

12. The computer program product as recited in claim 11, wherein said random test matrix Ω is constructed by drawing entries from a normal distribution, drawing entries from a uniform distribution, or drawing independent Rademacher entries.

13. The computer program product as recited in claim 8, wherein values of said input matrix are between zero and one.

14. The computer program product as recited in claim 8, wherein the program code further comprises the programming instructions for:
storing said computed product in 8-bit floating-point notation.

15. A system, comprising:
a memory for storing a computer program for image compression using mixed-precision matrix sketching; and
a processor connected to the memory, wherein the processor is configured to execute program instructions of the computer program comprising:
receiving an input matrix corresponding to an image;
receiving a target rank k;
creating a sketching matrix of said input matrix;
computing a product of said input matrix and said sketching matrix using 8-bit floating-point precision;
performing a decomposition of said computed product to determine a basis matrix Q for said input matrix using 64-bit floating-point precision;
computing a matrix B, which is smaller than said input matrix, using said basis matrix Q;
computing a singular value decomposition of said matrix B to obtain right singular vectors V, approximate left singular vectors Ũ and corresponding singular values Σ;
computing left singular vectors U by pre-multiplying said approximate left singular vectors Ũ by said basis matrix Q; and
selecting a top k singular values and vectors corresponding to said left singular vectors U, said corresponding singular values Σ, and said right singular vectors V thereby compressing said image.

16. The system as recited in claim 15, wherein said sketching matrix of said input matrix is created using a count sketch technique.

17. The system as recited in claim 16, wherein said count sketch technique comprises:
hashing each column of said input matrix with a value uniformly sampled from a range of sketch sizes; and
flipping a sign of each column with probability 50%, and then summing up columns with a same hash value.

18. The system as recited in claim 15, wherein said sketching matrix of said input matrix is created based on a drawing of a random test matrix Ω, wherein values of said random test matrix Ω are ±1.

19. The system as recited in claim 18, wherein said random test matrix Q is constructed by drawing entries from a normal distribution, drawing entries from a uniform distribution, or drawing independent Rademacher entries.

20. The system as recited in claim 15, wherein values of said input matrix are between zero and one.
